(19) United States
(12) Patent Application Publication
(10) Pub. No.: US 2008/0134001 A1
(43) Pub. Date: Jun. 5, 2008

(54) METHOD AND APPARATUS FOR CHECKING CORRECTION ERRORS USING CYCLIC REDUNDANCY CHECK

(75) Inventor: Jin-seok HONG, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/689,627

(22) Filed: Mar. 22, 2007

(30) Foreign Application Priority Data
Dec. 4, 2006 (KR) 2006-124044

(51) Int. Cl. H03M 13/00

(52) U.S. Cl. 714/758

(57) ABSTRACT

A method and apparatus for checking correction errors using a cyclic redundancy check (CRC). The method includes calculating and storing a syndrome from a received word; outputting an error value generated by correcting errors in the received word using a CRC after binding the error value to bits; dividing the error value outputted in bits into a first function unit and a second function unit; detecting a first modular value in which the first function unit is modularized using a look up table; generating a second modular value by performing modular arithmetic on the second function unit; operating and re-modularizing the first modular value and the second modular value in order to generate a part syndrome value; and accumulating the part syndrome value in order to determine errors in error correction.

### CROSS-REFERENCE TO RELATED APPLICATIONS

This application claims the benefit of Korean Patent Application No. 2006-124044, filed on Dec. 7, 2006, in the Korean Intellectual Property Office, the disclosure of which is incorporated herein in its entirety by reference.

### BACKGROUND OF THE INVENTION

1. Field of the Invention

Aspects of the present invention relate to a method of correcting errors in data communication and, more particularly, to a method and apparatus for checking correction errors using a cyclic redundancy check (CRC).

2. Description of the Related Art

An error detection code (EDC) is used to determine whether a received or read signal in a communication or storage system contains an error. A parity check, a cyclic redundancy check (CRC), or the like is used to detect errors that can occur in a message transmitted in data communication. Accordingly, errors that have occurred in a received word included in a received message can be detected. A transmitter transmits error-correction data, which is used to check for errors, along with a message. A receiver detects errors based on the error-correction data. In CRC, the error-correction data is added to the message and, when an error is included in a channel, the receiver can detect the error using simple modular arithmetic.

FIG. 1 illustrates a conventional storage apparatus and communication apparatus using a CRC. When an information word in bit-stream form is inputted, a code word is generated by encoding, which adds parity to the bit-stream. When the bit-stream in a number of K ciphers is in a polynomial expression, the information word can be expressed as I(x)=i^{k-1}x^{k-1}+ . . . +i⁰x⁰, where i^{k} is zero or one, depending on the value of the corresponding bit. When a value, in which the information word is modularized, is added to the information word as a parity in order to encode the information word, the information word becomes (iⁿ⁻¹xⁿ⁻¹+ . . . +i⁰x^{n-k})+(iⁿ⁻¹xⁿ⁻¹+ . . . +i⁰x^{n-k}) mod G(x). G(x) is a predetermined generator polynomial. The calculation result is a code word of n−1 difference in C(x)=cⁿ⁻¹xⁿ⁻¹+ . . . +c⁰x⁰ form.

When the code word generated as described above is transmitted through a channel, a receiver receives a received word in R(x)=rⁿ⁻¹xⁿ⁻¹+ . . . +r⁰x⁰ form. Noise E(x)=eⁿ⁻¹xⁿ⁻¹+ . . . +e⁰x⁰ may occur while the code word is transmitted through the channel. Accordingly, the received word can be expressed as the sum of the code word and the noise, such as (cⁿ⁻¹+eⁿ⁻¹)xⁿ⁻¹+ . . . +(c⁰+e⁰)x⁰. If the noise does not exist in the received word, the received word becomes the code word. When such a received word is modularized to G(x) via a decoding process, the same bit values are added to each coefficient and thus the remaining value becomes 0, as shown in Equation 1.

$$\begin{matrix}C ( x ) mod G ( x ) = ( {c}_{n - 1} {x}^{n - 1} + … + {c}_{0} {x}^{0} ) \text{mod} G ( x ) \\ = \{ ( {i}_{k - 1} {x}^{n - 1} + … + {i}_{0} {x}^{n - k} ) + \\ ( {i}_{k - 1} {x}^{n - 1} + … + {i}_{0} {x}^{n - k} ) \text{mod} G ( x ) \} \\ \text{mod} G ( x ) \\ = ( {i}_{k - 1} {x}^{n - 1} + … + {i}_{0} {x}^{n - k} ) \text{mod} G ( x ) + \\ ( {i}_{k - 1} {x}^{n - 1} + … + {i}_{0} {x}^{n - k} ) \text{mod} G ( x ) \\ = \{ ( {i}_{k - 1 +} {i}_{k - 1} ) {x}^{n - 1} + … + ( {i}_{0} + {i}_{0} ) {x}^{n - k} ) \} \\ \text{mod} G ( x ) \\ = 0\end{matrix} \qquad [ Equation 1 ]$$

However, when there is noise, the received word is the sum of the code word and the noise. Thus, when the received word is modularized to G(x), the code word and the noise are each modularized and each remaining value is added as shown in Equation 2. When the code word is modularized, the result is 0, since this is equal to the case where there is no noise. However, when the noise is modularized, the result is not 0, and thus the sum of the remaining values is not 0. The remaining values in which the received word is modularized to G(x) are called a CRC syndrome. Accordingly, whether the received word includes an error is determined based on whether the remaining value is 0 after modularizing the received word to G(x).

$$\begin{matrix}R ( x ) \text{mod} G ( x ) = ( {r}_{n - 1} {x}^{n - 1} + … + {r}_{0} {x}^{0} ) \text{mod} G ( x ) \\ = \{ ( {c}_{n - 1 +} {e}_{n - 1} ) {x}^{n - 1} + … + \\ ( {c}_{0} + {e}_{0} ) {x}^{0} \} \text{mod} G ( x ) \\ = ( {c}_{n - 1} {x}^{n - 1} + … + {c}_{0} {x}^{0} ) \text{mod} G ( x ) + \\ ( {e}_{n - 1} {x}^{n - 1} + … + {e}_{0} {x}^{0} ) \text{mod} G ( x ) \\ = ( {e}_{n - 1} {x}^{n - 1} + … + {e}_{0} {x}^{0} ) \text{mod} G ( x )\end{matrix} \qquad [ Equation 2 ]$$

Conventional methods used in a CRC encoding/decoding apparatus that generates CRC parity/syndrome use a linear feedback shift register (LFSR) as illustrated in FIG. 2 and an XOR array as illustrated in FIG. 3.

FIG. 2 illustrates a conventional CRC encoding/decoding apparatus 10 using a series calculation method. The CRC encoding/decoding apparatus 10 includes an exclusive OR 11 and a delay element 12. In the CRC encoding/decoding apparatus 10, calculation is performed in one bit units. Specifically, when an information word or a code word in a bit unit is sequentially inputted from a most significant bit (MSB), which is a higher order, or is sequentially inputted from a least significant bit (LSB), which is a lower order, encoding/decoding can be performed efficiently using a shift register.

FIG. 3 illustrates a conventional CRC encoding/decoding apparatus 20 using a parallel calculation method. Parallel calculation is performed on data inputted as a byte (8 bits) unit or a word (16 bits) unit via an exclusive OR (hereinafter, referred to as XOR) array 23 in parallel with data stored in a resistor 22. However, as speed of data transmission increases to 10 Gbps, the speed of a processor and the throughput of a controller 21 are limited while applying a parallel structure to the data inputted as a byte or word.

Sequential inputs of the information word/received word from the MSB or the LSB may be impossible or inefficient based on the application of the CRC encoding/decoding apparatus. In a communication system, a system which received a CRC code word generated in another system may change a part of the data. Calculating a CRC code of an entire CRC code word that has been changed is very inefficient and the system's speed may decrease as a result. Accordingly, it is more efficient to apply a parity of the previously generated code word using the changed data. In a storage system, an error in a received word of a read signal is corrected using a separate error correction code. The CRC code is used to determine whether the error remains. When data, which has been error corrected, is decoded, using the CRC encoding/decoding apparatus shown in FIG. 2 may be structurally simple but takes time. Accordingly, it is more efficient to decode data changed via the error correction.

In recent high speed storage systems, high speed processing is difficult when the CRC is performed after the error correction. Thus, the CRC code is decoded by calculating a CRC syndrome, which is calculated by performing CRC decoding on a received word including an error. The pre-calculated CRC syndrome is renewed using correction information. Error correction is performed simultaneously. The correction information is inputted non-sequentially and can be applied not only in decoding but also in parity encoding of the CRC code, which is inputted non-sequentially.

Various methods for increasing the speed of CRC encoding/decoding when the information word or the received word is inputted non-sequentially have been suggested. A first method generates a finite field. This method takes advantage of a characteristic that the generation polynomial G(x) shown in encoding/decoding processes of FIG. 1 is generally formed of (x+1) multiplied by an irreducible polynomial G′(x) that cannot be cancelled when modular arithmetic is performed on the irreducible polynomial G′(x). When using the finite field, the modular arithmetic becomes simple and the result of the modular arithmetic can be restored to the generation polynomial G(x). Conversion to a finite field element is required in order to realize advantages of the simplified calculation. Accordingly, a look up table should be preset.

When the degree of the generation polynomial G(x) is low, the encoding/decoding processes can be performed quickly. However, when the degree of the generation polynomial G(x) is high, the capacity of the look up table increases, and thus the capacity of the encoding/decoding apparatus is limited. For example, a 32 degree generation polynomial G(x) is not suitable, since the size of the look up table becomes 2³².

According to a second method, a received word is inputted non-sequentially after being bound into bit units. As shown in Equation 3, the same CRC syndrome can be obtained even when the received word is modularized to G(x) by each bound bit and the remaining values are accumulated. Moreover, when the code word is modularized to G(x), the result is 0, and thus the same result can be obtained only when an error value is modularized to G(x) by each bound bit and then accumulated.

Here, “each bound bit” means that a plurality of bits is bound by one factor in the received word, expressed in bits of a higher degree, as shown in Equation 3.

$$\begin{matrix}R ( x ) \text{mod} G ( x ) = \{ ( {r}_{n - 1} {x}^{n - 1} + … ) + … + \\ ( {r}_{q} {x}^{q} + … + {r}_{p} {x}^{p} ) + … + \\ ( … + {r}_{0} {x}^{0} ) \} \text{mod} G ( x ) \\ = … + ( {r}_{q} {x}^{q} + … + {r}_{p} {x}^{p} ) \text{mod} G ( x ) + … \\ = … + \{ ( {c}_{q} + {e}_{q} ) {x}^{q} + … + ( {c}_{p} + {e}_{p} ) {x}^{p} \} \\ \text{mod} G ( x ) + … \\ = … + \{ ( {c}_{q} + {e}_{q} ) {x}^{q} + … + ( {c}_{p} + {e}_{p} ) {x}^{p} \} \\ \text{mod} G ( x ) + … \\ = … + ( {e}_{q} {x}^{q} + … + {e}_{p} {x}^{p} ) \text{mod} G ( x ) + … \\ = … + ( {e}_{q} {x}^{q - p} + … + {e}_{p} {x}^{0} ) {x}^{p} \\ \text{mod} G ( x ) + … \\ = … + {E}^{′} ( x ) {x}^{p} \text{mod} G ( x ) + …\end{matrix} \qquad [ Equation 3 ]$$

When the received word is inputted non-sequentially as shown in Equation 3, remainders obtained by modularizing error components in each bound bit to G(x) can be called a part syndrome. A value obtained by accumulating the part syndrome is a syndrome, and searching only for an error value in the received word is generally called an error correction. Accordingly, the syndrome is a result of modularizing the error component obtained by the error correction.

Based on the above, Equation 4 is used to perform modular arithmetic on the generation polynomial G(x) when an index p can be substituted in 2048a+128b+8c from an error value E′(x)x^{p} inputted by each bound bit.

E(x)modG(x)=(E′(x)modG(x))(x²⁰⁴⁸modG(x))^{a}(x¹²⁸modG(x))^{b}(x⁸modG(x))^{c} [Equation 4]

Since the look up table is not used, the capacity of the encoding/decoding apparatus is not limited. However, the encoding/decoding processes are performed slowly because a loop operation is used.

### SUMMARY OF THE INVENTION

Aspects of the present invention provide a method and apparatus for cyclic redundancy checking correction errors at high speed, while correcting errors detected in an information word/received word inputted non-sequentially.

According to an aspect of the present invention, there is provided a method of checking correction errors, the method including: calculating and storing a syndrome from a received word; outputting an error value generated by correcting errors in the received word using a CRC (cyclic redundancy check) after binding the error value to bits; dividing the error value outputted in bits into a first function unit and a second function unit; detecting a first modular value in which the first function unit is modularized using a look up table; generating a second modular value by performing modular arithmetic on the second function unit; operating and re-modularizing the first modular value and the second modular value in order to generate a part syndrome value; and accumulating the part syndrome value in order to determine errors in the error correction.

The error value outputted in bits may be inputted non-sequentially.

The error value outputted in bits may be set as E′(x)·x^{k·2′+d}, the first function unit may be divided by E′(x)·x^{d} and the second function unit may be divided by x^{k·2′}.

Capacity of the look up table and speed of generating the second modular value may be determined based on the variable t.

The capacity of the look up table and the speed of generating the second modular value may increase as the variable t decreases and the capacity of the look up table and the speed of generating the second modular value may decrease as the variable t increases.

The errors in the error correction may be determined by performing an XOR operation on the accumulated part syndrome value and the value of the stored syndrome.

It may be determined that the errors in the error correction have not occurred when the result of the XOR operation is 0, and it may be determined that the errors in the error correction have occurred when the result of the XOR operation is not 0.

According to another aspect of the present invention, there is provided an apparatus for checking correction errors, the apparatus including: an error corrector which outputs an error value generated by correcting errors of a received word using a CRC after binding the error value to bits; a modular which divides the error value outputted in bits into a first function unit and a second function unit and then generates part syndrome values by performing modular arithmetic on each of the first function unit and the second function unit; a syndrome storage unit which stores a syndrome calculated from the received word and accumulates and stores a part syndrome value of the error value outputted in bits; and a first logic operator which determines errors in the error correction by operating the value of the stored syndrome and the part syndrome value.

The modular may include: a controller which divides the error value outputted in bits into the first function unit and the second function unit; a look up table which stores a first modular value of the first function unit; a first modular unit which generates a second modular value by performing modular arithmetic on the second function unit; and a second modular unit which operates and then modularizes the first modular value and the second modular value in order to output the value of the syndrome.

The value of the syndrome accumulated by performing the XOR operation may be stored in the syndrome storage unit.

The apparatus may further include a received word syndrome calculator which calculates the syndrome of the received word using a CRC.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a diagram illustrating a conventional storage apparatus and communication apparatus using a cyclic redundancy check (CRC);

FIG. 2 is a diagram illustrating a conventional CRC encoding/decoding apparatus using a series calculation method;

FIG. 3 is a diagram illustrating a conventional CRC encoding/decoding apparatus using a parallel calculation method;

FIG. 4 is a diagram illustrating a CRC decoding apparatus according to an embodiment of the present invention;

FIG. 5 is a diagram illustrating a high speed modularizer according to an embodiment of the present invention; and

FIG. 6 is a flowchart of a method of checking errors in error correction according to an embodiment of the present invention.

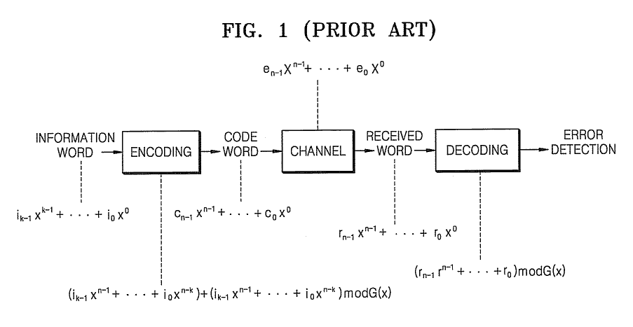

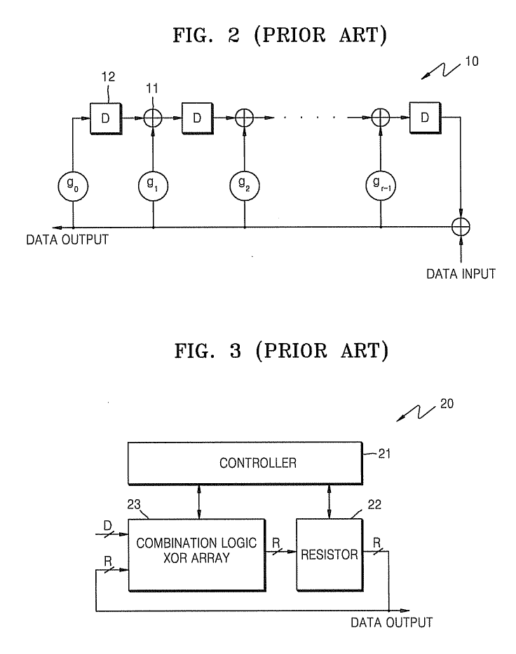

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

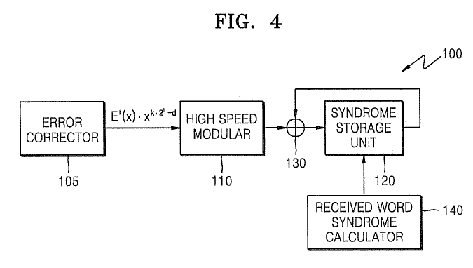

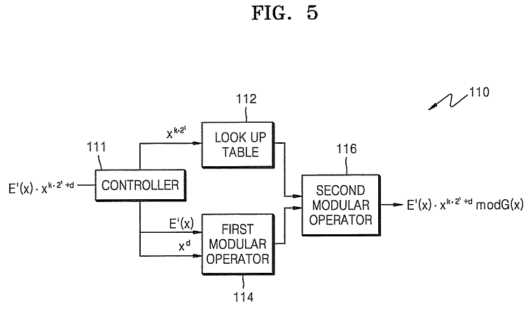

An apparatus to check errors in error corrections at high speed according to an embodiment of the present invention will be described with reference to FIGS. 4 and 5. Errors in the error correction indicates a state in which the error correction has not been completely performed, when the errors occur while transmitting a received word and while correcting the errors using a cyclic redundancy check (CRC). Errors in the error correction can be determined using the apparatus illustrated in FIGS. 4 and 5.

FIG. 4 illustrates a CRC decoding apparatus 100 according to an embodiment of the present invention. As illustrated in FIG. 4, the CRC decoding apparatus 100 includes an error corrector 105, which outputs error values E′(x)·x^{p} in each bound bit non-sequentially from the entire error values E(x); a high speed modular 110, which modularizes the error values E′(x)·x^{p} in each bound bit at high speed in order to generate a part syndrome; a syndrome storage unit 120, which initially stores a received word syndrome and accumulates part syndromes generated while correcting errors; an exclusive OR (XOR) 130; and a received word syndrome calculator 140, which calculates CRC syndromes of the received word before detecting the errors.

FIG. 5 illustrates the high speed modular 110 according to an embodiment of the present invention. The high speed modular 110 includes a controller 111, a look up table 112, a first modular operator 114, and a second modular operator 116.

First, an index of the detected error values E′(x)x^{p} in each bound bit is expressed as p=k·2^{t}+d and the error values E′(x)x^{p} in each bound bit outputted from the error corrector 105 is inputted to the high speed modular 110 in order to be checked as to whether error correction was performed properly. The high speed modular 110 modularizes the error values E′(x)·x^{k·2′+d} in each bound bit in order to transmit the part syndrome to the syndrome storage unit 120. The syndrome storage unit 120 continuously accumulates and stores the part syndrome. The XOR 130 performs an XOR operation on the pre-accumulated syndrome values and the values of the newly inputted part syndrome, then outputs the results to the syndrome storage unit 120. The syndrome storage unit 120 stores the results as part syndrome values of the error values E′(x).

Values generated by the received word syndrome calculator 140 before the error corrections and stored in the syndrome storage unit 120 are the entire errors E(x) as shown in Equation 2. When the error corrector 105 successfully finds the entire error values and the high speed modular 110 calculates and accumulates the part syndromes, the result is equal to the value generated by the received word syndrome calculator 140. Accordingly, the value stored in the syndrome storage unit 120 becomes 0. If the result is not 0, error correction has not been performed properly and the corresponding code word is transmitted again. When the syndrome of the received word is calculated and stored, and error values are non-sequentially inputted by performing the error corrections, it is determined whether the error correction was successfully performed by performing modular arithmetic on each error value and accumulating the error values with the XOR operation.

As illustrated in FIG. 5, the controller 111 divides the error values E′(x)·x^{k·2′+d} in each bound bit inputted to the high speed modular 110 into E′(x), x^{k·2′}, and x^{d} in order to input each into the look up table 112 and the first modular operator 114. x^{k·2′} is inputted to the look up table 112 in order to obtain a value of x^{k·2′} mod G(x). A value of E′(x)·x^{d} mod(x) is obtained by inputting E′(x) and x^{d} into the first modular operator 114. Accordingly, when the values of x^{k·2′} mod G(x) and E′(x)·x^{d} mod G(x) are inputted into the second modular operator 116, the second modular operator 116 multiplies the values and performs the modular arithmetic in order to generate a final value E′(x)·x^{k·2′+d} mod G(x) and to output the final value to the syndrome storage unit 120.

The high speed modular 110 uses a basic modular arithmetic equation and obtains E′(x)·x^{k·2′+d} mod G(x) as given by Equation 5 below.

E′(x)·x^{k·2′+d}modG(x)=(x^{k·2′}modG(x))(E′(x)x^{d}modG(x))modG(x) [Equation 5]

The controller 111 divides the error values E′(x)·x^{k·2′+d} in each bound bit using E′(x), x^{k·2′}, and x^{d} in order to obtain a modular value of x^{k·2′} using the look up table 112 and modularizes E′(x) and x^{d} by using the first modular operator 114 and a conventional LFSR circuit method.

The size of the look up table 112 and calculation speed of the first modular operator 114 can be regulated using a value of t inputted to the look up table 112. When the value of t decreases, the size of the look up table 112 and the calculation speed of the first modular operator 114 increase. However, when the value of t increases, the size of the look up table 112 and the calculation speed of the first modular operator 114 decrease, while the size of a circuit of the first modular operator 114 increases. Thus, the size of the look up table 112 and the calculation speed of the first modular operator 114 are in a trade-off relationship. Accordingly, the value of t can be regulated based on the desired speed in order to determine the size of the look up table 112 and the calculation speed of the first modular operator 114.

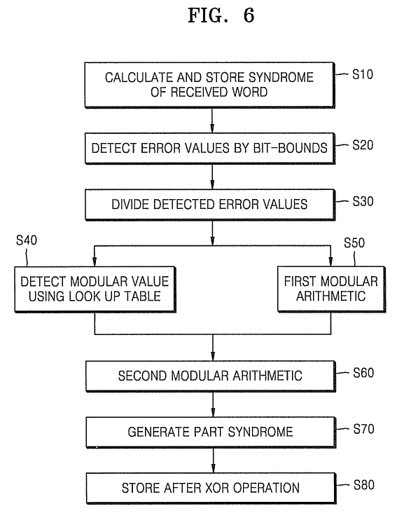

FIG. 6 is a flowchart of a technique of checking for errors in error correction according to an embodiment of the present invention. In operation S10, the received word syndrome calculator 140 calculates a syndrome value from a received word and stores the syndrome value in the syndrome storage unit 120. In operation S20, the error corrector 105 detects error values in each bound bit by correcting errors in the received word and outputs the error values in each bound bit to the high speed modular 110. In operation S30, the controller 111 of the high speed modular 110 divides the detected error values in each bound bit. The error values E′(x)·x^{k·2′+d} in each bound bit are divided using E′(x), x^{k·2′}, and x^{d}. A modular value of x^{k·2′} is detected in operation S40 using the look up table 112. Modular multiplication arithmetic is performed on E′(x) and x^{d} in operation S50 via the first modular operator 114. Operations S40 and S50 may occur simultaneously.

In operation S60, the second modular operator 116 multiplies x^{k·2′} mod G(x) and E′(x)·x^{d} mod G(x) and performs the modular arithmetic. In operation S70, a part syndrome value is generated. In operation S80, an XOR operation is performed on the part syndrome value and a value stored in the syndrome storage unit 120 and the result is stored in the syndrome storage unit 120. When a new syndrome value is generated by accumulating all part syndrome values, it is determined whether an error occurred during error correction based on the result of the generated new syndrome value.

As described above, by presetting a value of t inputted to the look up table 112, the size of the look up table 112 and the calculation speed of the first modular operator 114, which are in a trade-off relationship, can be regulated. Also, aspects of the present invention used to correct errors during the decoding of the received word by non-sequentially inputting the error values can also be used to generate CRC parity while an information word is non-sequentially input during encoding processes or while generating a CRC syndrome while the received word is non-sequentially input during decoding processes. Accordingly, aspects of the present invention can be widely applied to technologies related to CRC on the information word/received word/error values.

Error correction techniques according to aspects of the present invention may be recorded in computer-readable media including program instructions to implement various operations embodied by a computer. The media may also include, alone or in combination with the program instructions, data files, data structures, and the like. Examples of computer-readable media include magnetic media such as hard disks, floppy disks, and magnetic tape; optical media such as CD ROM disks and DVD; magneto-optical media such as optical disks; and hardware devices that are specially configured to store and perform program instructions, such as read-only memory (ROM), random access memory (RAM), flash memory, and the like; and a computer data signal embodied in a carrier wave comprising a compression source code segment and an encryption source code segment (such as data transmission through the Internet). Examples of program instructions include both machine code, such as produced by a compiler, and files containing higher level code that may be executed by the computer using an interpreter. The described hardware devices may be configured to act as one or more software modules in order to perform the operations of the above-described embodiments of the present invention.

As described above, by regulating the value of t of the error values E′(x)·x^{k·2′+d} in each bound bit non-sequentially inputted by a CRC, the capacity of the apparatus to check error correction and the speed of checking the error correction, which are in a trade-off relationship, can be suitably controlled.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A method of checking for errors in error correction, the method comprising:
calculating and storing a syndrome from a received word;
outputting an error value generated by correcting the errors in the received word using a CRC (cyclic redundancy check) after binding the error value to bits;
dividing the error value outputted in bits into a first function unit and a second function unit;
detecting a first modular value in which the first function unit is modularized using a look up table;
generating a second modular value by performing modular arithmetic on the second function unit;
operating and re-modularizing the first modular value and the second modular value in order to generate a part syndrome value; and
accumulating the part syndrome value in order to determine the errors in the error correction.

2. The method of claim 1, wherein the error value outputted in bits is inputted non-sequentially.

3. The method of claim 2, wherein the error value outputted in bits is E′(x)·x^{k·2′+d}, the first function unit is E′(x)·x^{d}, and the second function unit is x^{k·2′}.

4. The method of claim 3, wherein the size of the look up table and speed of generating the second modular value are determined based on the variable t.

5. The method of claim 4, wherein the capacity of the look up table and the speed of generating the second modular value increase as the variable t decreases and the capacity of the look up table and the speed of generating the second modular value decrease as the variable t increases.

6. The method of claim 1, further comprising:
determining errors in the error correction by performing an XOR operation on the accumulated part syndrome value and the stored syndrome.

7. The method of claim 6, further comprising:
determining that the errors in the error correction have not occurred when the result of the XOR operation is 0; and
determining that the errors in the error correction have occurred when the result of the XOR operation is not 0.

8. An apparatus to check for errors in error correction, the apparatus comprising:
an error corrector to output an error value generated by correcting the errors of a received word using a cyclic redundancy check (CRC) after binding the error value to bits;
a modular to divide the error value outputted in bits into a first function unit and a second function unit and to generate part syndrome values by performing modular arithmetic on the first function unit and the second function unit;
a syndrome storage unit to store a syndrome calculated from the received word and to accumulate and store a part syndrome value of the error value outputted in bits; and
a first logic operator to determine the errors in the error correction based on the value of the stored syndrome and the accumulated part syndrome value.

9. The apparatus of claim 8, wherein the modular comprises:
a controller to divide the error value outputted in bits into the first function unit and the second function unit;
a look up table to store a first modular value of the first function unit;
a first modular unit to generate a second modular value by performing modular arithmetic on the second function unit; and
a second modular unit to operate on and then modularize the first modular value and the second modular value in order to output the part syndrome value.

10. The apparatus of claim 9, wherein the error value outputted in bits is inputted non-sequentially.

11. The apparatus of claim 10, wherein the controller divides the error value outputted in bits by setting the first function unit as E′(x)·x^{d} and setting the second function unit as x^{k·2′}.

12. The apparatus of claim 11, wherein a size of the look up table and a speed of generating the second modular value are determined based on the variable t.

13. The apparatus of claim 8, wherein the first logic operator is an XOR gate.

14. The apparatus of claim 13, wherein:
the first logic operator performs an XOR operation using the value of the stored syndrome and the accumulated part syndrome value; and
the first logic operator determines that the errors in the error correction have not occurred when the result of the XOR operation is 0; and
the first logic operator determines that the errors in the error correction have occurred when the result of the XOR operation is not 0.

15. The apparatus of claim 14, wherein the result of the XOR operation is stored in the syndrome storage unit.

16. The apparatus of claim 8, further comprising a received word syndrome calculator which calculates the syndrome of the received word using a CRC.

17. A computer readable recording medium having recorded thereon a program to execute the method of claim 1.

18. A method of generating a cyclic redundancy check (CRC) parity during an encoding process, the method comprising:
dividing an inputted portion of an information word into a first function unit and a second function unit, wherein the portion of the information word is input non-sequentially;
detecting a first modular value in which the first function unit is modularized using a look up table;
generating a second modular value by performing modular arithmetic on the second function unit;
combining the first modular value and the second modular value to generate a part syndrome value; and
accumulating part syndrome values to generate a CRC parity for the information word.

19. The method of claim 18, wherein the detecting of the first modular value and the generating of the second modular value are performed simultaneously.

20. An apparatus to generate a cyclic redundancy check (CRC) parity for an information word, the apparatus comprising:
a modular to divide an inputted portion of the information word into a first function unit and a second function unit and to generate a part syndrome value using the first function unit and the second function unit;
a storage unit to store the part syndrome values; and
an accumulator to accumulate the part syndrome values and to generate a CRC parity for the information word.

21. The apparatus of claim 20, wherein the modular comprises:
a controller to divide the portion of the information word into the first function unit and the second function unit;
a look up table to store a first modular value of the first function unit;
a first modular unit to generate a second modular value by performing modular arithmetic on the second function unit; and
a second modular unit to operate on and modularize the first module value and the second modular value and to output the result as the part syndrome value.

22. The apparatus of claim 20, wherein the inputted portion of the information word is inputted non-sequentially.

23. The method according to claim 1, wherein the detecting of the first modular value and the dividing of the second modular value are performed simultaneously.
